(19) United States
(12) Patent Application Publication
(10) Pub. No.: US 2011/0006828 A1
(43) Pub. Date: Jan. 13, 2011

(54) DIFFERENTIAL TYPE LEVEL SHIFTER

(75) Inventors: Pei-Yuan Chen, Hsin-Chu (TW); Chu-Chiao Yu, Hsin-Chu (TW); Yen-Ping Wang, Hsin-Chu (TW)

Correspondence Address: APEX JURIS, PLLC, 12733 LAKE CITY WAY NORTHEAST, SEATTLE, WA, 98125, US

(73) Assignee: GRENERGY OPTO,INC., Hsin-Chu (TW)

(21) Appl. No.: 12/500,874

(22) Filed: Jul. 10, 2009

(51) Int. Cl. H03L 5/00

(52) U.S. Cl. 327/333

(57) ABSTRACT

This patent discloses a differential type level shifter, comprising: a differential pair of transistors, having a pair of gate terminals, a pair of drain terminals and a common source terminal, with the pair of gate terminals coupled to a first clock signal and a second clock signal; a current source, coupled between the common source terminal and a reference ground, used to provide a bias current; and a pair of loading resistors, having a common end and a pair of output ends, with the common end coupled to a power line, the pair of output ends coupled to the pair of drain terminals; wherein the pair of drain terminals are used to generate a set signal and a reset signal in response to the first clock signal and the second clock signal.

### BACKGROUND OF THE INVENTION

1. Field of the Invention

The present invention relates to a level shifter, and more particularly to a differential type level shifter capable of performing common-mode glitch interference cancellation in a half-bridge or full-bridge high-side driver.

2. Description of the Related Art

To describe the related art of the present invention, the relation between a level shifter and a half-bridge or full-bridge high-side driver shall be introduced first. Please refer to FIG. 1, which shows the architecture of a typical half-bridge driver 100. As shown in FIG. 1, the typical half-bridge driver 100 at least includes a pulse generator 101, a level shifter 102, a pulse filter 103, and a latch 104.

The pulse generator 101 is used for generating a first clock signal CLK and a second clock signal CLKB, wherein the first clock signal CLK is interleaved with the second clock signal CLKB. The level shifter 102 is used to up shift the first clock signal CLK and the second clock signal CLKB from low side to provide counterpart signals for the pulse filter 103 at high side. The pulse filter 103 is used for cancelling a common-mode glitch interference accompanying the power lines of V_{BOOT} and HB, and generating a set signal V_{SET} and a reset signal V_{RESET} to the latch 104. The latch 104 is used for sending a signal to a driver to switch a high-side power MOSFET During the switching, a glitch is generated due to the capacitive characteristic of a capacitor C_{BOOT}, i.e., the voltage difference hold between the two plates of a capacitor will not change abruptly. As a result, the certain period the capacitor takes to reach a stable state causes a glitch period. The pulse filter 103 is therefore used to deal with the glitch problem to prevent false triggering of the latch 104.

One solution to improve the glitch immunity of the half-bridge or full-bridge high-side driver is to use a level shifter of symmetric structure. Please refer to FIG. 2, which shows a circuit diagram of a prior art level shifter 200 driving a latch 210. As shown in FIG. 2, the prior art level shifter 200 comprises a pair of loading resistors 201˜202, a first pair of NMOS transistors 203˜204 and a second pair of NMOS transistors 205˜206.

By the symmetric structure, the voltage potentials V_{SET} and V_{RESET} at the drain terminals of the first pair of NMOS transistors 203˜204 are supposed to change simultaneously when a glitch is produced in the power line V_{BOOT} so that the voltage difference between the drain terminals of the first pair of NMOS transistors 203˜204 remain unchanged and the latch 210 will not be false triggered. However, if the voltage potentials V_{SET} and V_{RESET} at the drain terminals of the first pair of NMOS transistors 203˜204 fall below a threshold voltage that the first pair of NMOS transistors 203˜204 and the second pair of NMOS transistors 205˜206 are forced to operate in triode region, then the latch 210 may be false triggered.

Therefore, there is a demand to provide a robust level shifter that can reduce the voltage dropt of the set signal and the reset signal in spite of the glitch to guarantee the normal operation of the latch.

### SUMMARY OF THE INVENTION

One objective of the present invention is to provide an effective and robust means for a level shifter to process an inherent glitch from a power line of a half-bridge or full-bridge high-side driver.

Another objective of the present invention is to provide a concise differential type level shifter capable of reducing an inherent glitch from a power line of a half-bridge or full-bridge high-side driver.

To achieve the foregoing objectives, the present invention provides a differential type level shifter, comprising: a differential type level shifter, used in a half-bridge or full-bridge high-side driver, the differential type level shifter comprising: a differential pair of transistors, having a pair of first terminals, a pair of second terminals and a common terminal, with the pair of first terminals coupled to a first clock signal and a second clock signal; a current source, coupled between the common terminal and a reference ground, used to provide a bias current; and a pair of loading devices, having a common end and a pair of output ends, with the common end coupled to a power line, the pair of output ends coupled to the pair of second terminals; wherein the pair of second terminals are used to generate a set signal and a reset signal in response to the first clock signal and the second clock signal.

To make it easier for our examiner to understand the objective of the invention, its structure, innovative features, and performance, we use a preferred embodiment together with the attached drawings for the detailed description of the invention.

### BRIEF DESCRIPTION OF THE DRAWINGS

FIG. 1 shows the architecture of a typical half-bridge driver.

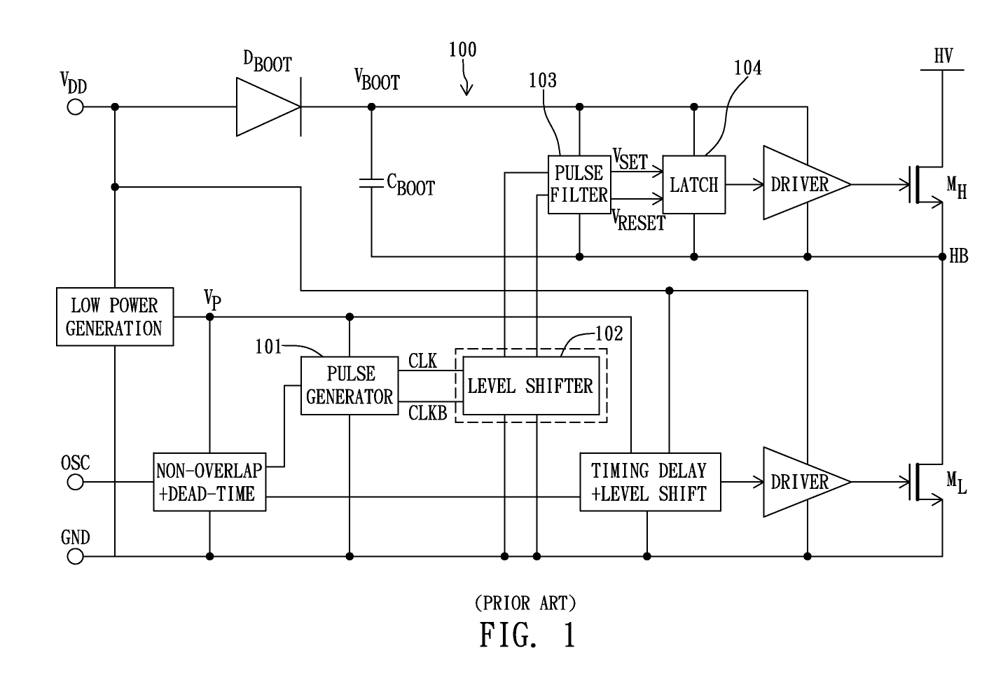

FIG. 2 is a circuit diagram of a prior art level shifter.

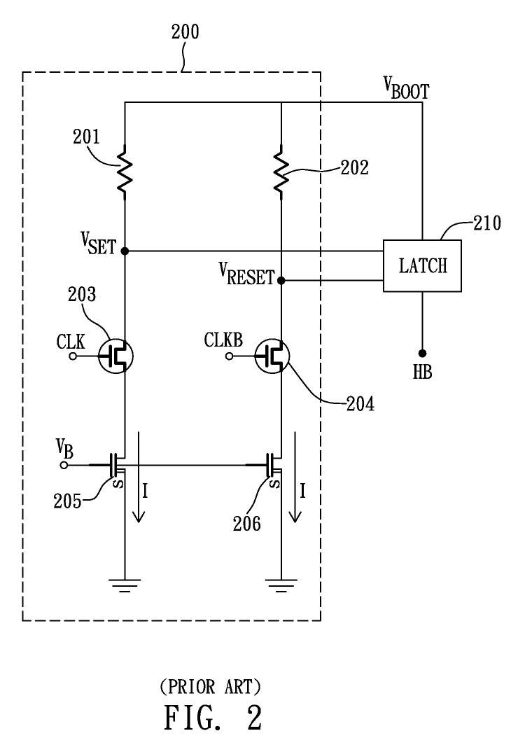

FIG. 3 is a circuit diagram of a level shifter according to a preferred embodiment of the present invention and a latch driven by the level shifter, the level shifter being capable of reducing an inherent glitch from a power line of a half-bridge or full-bridge high-side driver.

FIG. 4 is a circuit diagram of a level shifter according to another preferred embodiment of the present invention and a latch driven by the level shifter, the level shifter being capable of reducing an inherent glitch from a power line of a half-bridge or full-bridge high-side driver.

FIG. 5 is a waveform diagram of the circuit in FIG. 3.

### DETAILED DESCRIPTION OF THE PREFERRED EMBODIMENTS

The present invention will be described in more detail hereinafter with reference to the accompanying drawings that show the preferred embodiments of the invention.

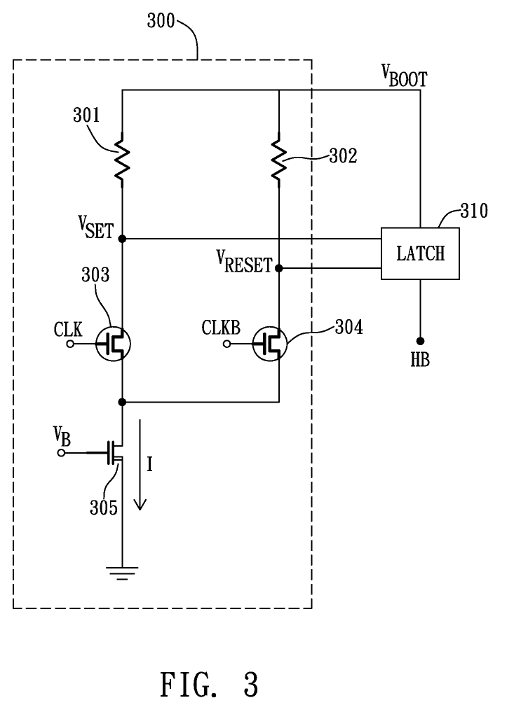

Please refer to FIG. 3, which shows a circuit diagram of a level shifter 300 according to a preferred embodiment of the present invention and a latch 310 driven by the level shifter 300, the level shifter 300 being capable of reducing an inherent glitch from a power line of a half-bridge or full-bridge high-side driver. As shown in FIG. 3, the level shifter 300 includes a pair of loading resistors 30˜302, a differential pair of transistors 303˜304, and a current source transistor 305.

In this embodiment, the pair of loading resistors 301˜302 have a common end, a pair of output ends, with the common end coupled to a power line V_{BOOT}, the pair of output ends coupled to the transistor 303, and the transistor 304. The differential pair of transistors 303˜304 have a pair of gate terminals, a pair of drain terminals, and a common source terminal, with the pair of drain terminals coupled to the output ends, the pair of gate terminals coupled to a first clock signal CLK and a second clock signal CLKB, and the common source terminal coupled to the current source transistor 305. The current source transistor 305 has a drain terminal, a gate terminal and a source terminal, with the drain terminal coupled to the common source terminal of the differential pair of transistors 303˜304, the gate terminal coupled to a DC bias voltage V_{B}, and the source terminal coupled to a reference ground, wherein the current source transistor 305 is used to provide a bias current I, and the pair of drain terminals of transistors 303˜304 are used to generate a set signal V_{SET} and a reset signal V_{RESET} in response to the first clock signal CLK and the second clock signal CLKB.

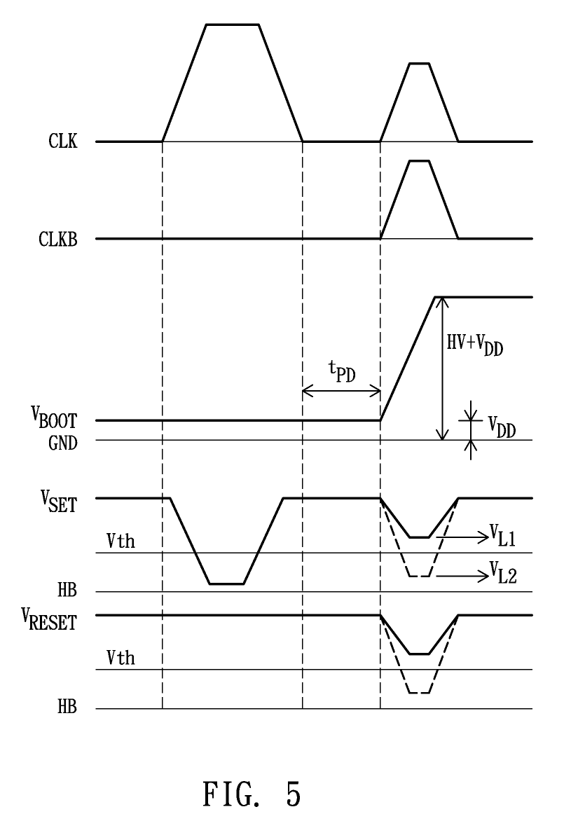

The operation principle of the circuit in FIG. 3 will be illustrated by taking the first clock signal CLK being at a high level and the second clock signal CLKB being at a low level as an example. The resulted waveform of the related signals of CLK, CLKB, V_{BOOT}, V_{SET} and V_{RESET} is shown in FIG. 5. When the first clock signal CLK changes from a low level to a high level and the second clock signal CLKB stays at a low level, the transistor 303 will be turned-on and the transistor 304 will be turned-off that the set signal V_{SET} will exhibit a normal negative pulse and the reset signal V_{RESET} will stay at a high level. As can be seen in FIG. 5, the valley of the normal negative pulse of the set signal V_{SET} is below a threshold voltage Vₜₕ, which will cause an effective triggering of the latch 310, and the latch 310 will deliver a high level to drive a high side power switch (not shown in FIG. 3). After a propagation delay t_{PD}, the voltage of the power line V_{BOOT} will rise from V_{DD} to HV+V_{DD}, which will cause a glitch on the first clock signal CLK via a gate-drain parasitic capacitor across the drain terminal and the gate terminal of the transistor 303, and a glitch on the second clock signal CLKB via a gate-drain parasitic capacitor across the drain terminal and the gate terminal of the transistor 304. The glitch on the first clock signal CLK may turn on the transistor 303 and the glitch on the second clock signal CLKB may turn on the transistor 304, so that both the set signal V_{SET} and the reset signal V_{RESET} exhibit an infected negative pulse.

Due to the differential type design of the present invention, the bias current I in the current source transistor 305 is approximately divided into two currents I/2, I/2 for the transistor 303 and the transistor 304 respectively, so the infected negative pulses of the set signal V_{SET} and the reset signal V_{RESET} will have a valley level V_{L1}, which is much higher than the threshold voltage Vₜₕ to prevent false triggering of the latch 310. However, in prior art circuits of which the level shifter is not the differential type, a valley level V_{L2} of the set signal V_{SET} and the reset signal V_{RESET}, lower than the threshold voltage Vₜₕ, may false trigger the latch 310.

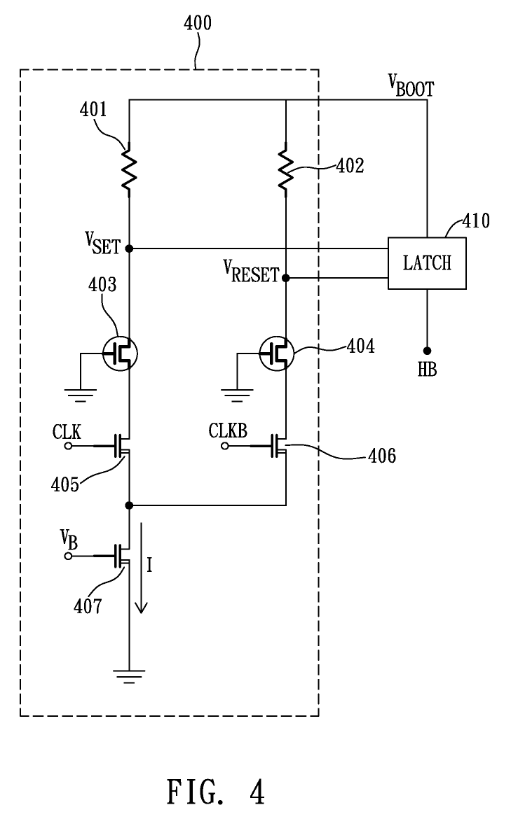

To further reduce the glitches on the first clock signal CLK and the second clock signal CLKB, a cascaded differential pair is implemented. Please refer to FIG. 4, which shows a circuit diagram of a level shifter 400 according to another preferred embodiment of the present invention and a latch 410 driven by the level shifter 400, the level shifter 400 being capable of reducing an inherent glitch from a power line V_{BOOT} of a half-bridge or full-bridge high-side driver. As shown in the FIG. 4, the level shifter 400 includes a pair of loading resistors 401˜402, a first differential pair of transistors 403˜404, a second differential pair of transistors 405˜406, and a current source transistor 407.

In this embodiment, the pair of loading resistors 401˜402 have a common end, a pair of output ends, with the common end coupled to a power line V_{BOOT}, the pair of output ends coupled to the first differential pair of transistors 403˜404. The first differential pair of transistors 403˜404 have a first pair of gate terminals, a first pair of drain terminals and a first pair of source terminals, with the first pair of drain terminals coupled to the first end and the second end of the pair of loading resistors 401˜402, the first pair of gate terminals coupled to a reference ground, and the first pair of source terminals coupled to the second pair of transistors 405˜406. The second differential pair of transistors 405˜406 have a second pair of gate terminals, a second pair of drain terminals and a common source terminal, with the second pair of drain terminals coupled to the first pair of source terminals, the second pair of gate terminals coupled to a first clock signal CLK and a second clock signal CLKB, and the common source terminal coupled to the current source transistor 407. The current source transistor 407 has a drain terminal, a gate terminal and a source terminal, with the drain terminal coupled to the common source terminal, the gate terminal coupled to a DC bias voltage V_{B}, and the source terminal coupled to the reference ground, wherein the current source transistor 407 is used to provide a bias current I, and the first pair of drain terminals are used to generate a set signal V_{SET} and a reset signal V_{RESET} in response to the first clock signal CLK and the second clock signal CLKB. It can be seen that the gate-drain parasitic capacitors across the second pair of drain terminals and the second pair of gate terminals are shielded by the first pair of transistors 403˜404, so the first clock signal CLK and the second clock signal CLKB can be less influenced by the interference from the power line V_{BOOT}, and the false triggering of the latch 410 can be further prevented.

Through the implementation of the above preferred embodiments of the present invention, a concise, effective and robust level shifter capable of processing an inherent glitch from a power line of a half-bridge or full-bridge high-side driver is attained.

While the invention has been described by way of examples and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance than the conventional structure and further complies with the patent application requirements and is submitted to the Patent and Trademark Office for review and granting of the commensurate patent rights.

What is claimed is:

1. A differential type level shifter, used in a half-bridge or full-bridge high-side driver, said differential type level shifter comprising:
a differential pair of transistors, having a pair of first terminals, a pair of second terminals and a common terminal, with said pair of first terminals coupled to a first clock signal and a second clock signal;
a current source, coupled between said common terminal and a reference ground, used to provide a bias current; and
a pair of loading devices, having a common end and a pair of output ends, with said common end coupled to a power line, said pair of output ends coupled to said pair of second terminals;
wherein said pair of second terminals are used to generate a set signal and a reset signal in response to said first clock signal and said second clock signal.

2. The differential type level shifter as claim 1, wherein said differential pair of transistors are NMOS transistors with said first terminals being gate terminals, said second terminals being drain terminals, and said common terminal being source terminal.

3. The differential type level shifter as claim 1, wherein said current source comprises an NMOS transistor.

4. The differential type level shifter as claim 1, wherein said loading devices comprises a pair of resistors.

5. A differential type level shifter, used in a half-bridge or full-bridge high-side driver, said differential type level shifter comprising:
a first differential pair of transistors, having a pair of first terminals, a pair of second terminals and a pair of third terminals, with said pair of first terminals coupled to a pair of reference voltages;
a second differential pair of transistors, having a pair of fourth terminals, a pair of fifth terminals and a common terminal, with said pair of fourth terminals coupled to a first clock signal and a second clock signal, said pair of fifth terminals coupled to said pair of third terminals;
a current source, coupled between said common terminal and a reference ground, used to provide a bias current; and
a pair of loading devices, having a common end and a pair of output ends, with said common end coupled to a power line, said pair of output ends coupled to said pair of second terminals;
wherein said pair of second terminals are used to generate a set signal and a reset signal in response to said first clock signal and said second clock signal.

6. The differential type level shifter as claim 5, wherein said first differential pair of transistors are NMOS transistors with the first terminals being gate terminals, the second terminals being drain terminals, and the third terminals being source terminals.

7. The differential type level shifter as claim 5, wherein said pair of reference voltages is supplied by said reference ground.

8. The differential type level shifter as claim 5, wherein said second differential pair of transistors are NMOS transistors with said fourth terminals being gate terminals, said fifth terminals being drain terminals, and said common terminal being source terminal.

9. The differential type level shifter as claim 5, wherein said current source comprises an NMOS transistor.

10. The differential type level shifter as claim 5, wherein said loading devices comprise a pair of resistors.
